(19) United States
(12) Patent Application Publication
(10) Pub. No.: US 2019/0273057 A1
(43) Pub. Date: Sep. 5, 2019

(54) SEMICONDUCTOR DEVICE AND MANUFACTURING METHOD OF THE SAME

(71) Applicant: RENESAS ELECTRONICS CORPORATION, Tokyo (JP)

(72) Inventor: Tamotsu OGATA, Tokyo (JP)

(21) Appl. No.: 16/278,959

(22) Filed: Feb. 19, 2019

(30) Foreign Application Priority Data
Mar. 2, 2018 (JP) 2018-037247

(51) Int. Cl. H01L 23/00

(52) U.S. Cl. CPC H01L 24/05; H01L 24/03; H01L 2224/05624; H01L 2224/05567; H01L 23/585; H01L 2924/05042; H01L 2924/05442; H01L 2224/0391; H01L 2224/03614; H01L 2924/04941

(57) ABSTRACT

To provide a semiconductor device that prevents a surface of a bonding pad from being made rough and can also reduce dimensions of the bonding pad, a semiconductor device according to an embodiment includes a bonding pad containing aluminum, a titanium nitride film, a passivation film, and a sidewall protection film including a first layer and a second layer. An opening is provided in the titanium nitride film and the passivation film. The opening includes a sidewall and exposes the bonding pad therethrough. The first layer of the sidewall protection film covers at least the titanium nitride film over the sidewall, and the second layer covers the first layer. A material forming the first layer and a material forming the second layer are different from each other in an etching rate in etching under the same condition.

### CROSS-REFERENCE TO RELATED APPLICATIONS

The disclosure of Japanese Patent Application No. 2018-037247 filed on Mar. 2, 2018 including the specification, drawings and abstract is incorporated herein by reference in its entirety.

### BACKGROUND

The present invention relates to a semiconductor device and a manufacturing method of a semiconductor device.

There are conventionally known semiconductor devices respectively described in Japanese Unexamined Patent Application Publication Nos. 2011-233746 and Hei 11(1999)-312670.

The semiconductor device described in Japanese Unexamined Patent Application Publication No. 2011-233746 includes a bonding pad containing aluminum, a titanium nitride (TiN) film arranged over the bonding pad, a first passivation film covering the bonding pad and the TiN film, and a second passivation film.

An opening is provided in the first passivation film and the TiN film to be located above the bonding pad. The second passivation film covers the sidewall of the opening provided in the first passivation film and the TiN film.

In the semiconductor device described in Japanese Unexamined Patent Application Publication No. 2011-233746, the second passivation film covers the sidewall of the opening provided in the first passivation film and the TiN film, thereby suppressing expansion in association with oxidation of the TiN film because of moisture. This is because, when the TiN film expands, it is likely that a crack is introduced into the TiN film to cause corrosion of wiring below the bonding pad.

The semiconductor device described in Japanese Unexamined Patent Application Publication No. Hei 11(1999)-312670 includes an aluminum (Al)-copper (Cu) film, an antireflection film arranged over the Al-Cu film, a passivation film covering the Al—Cu film and the antireflection film, and a sidewall protection film. The Al—Cu film serves as a bonding pad in the semiconductor device described in Japanese Unexamined Patent Application Publication No. Hei 11(1999)-312670.

The antireflection film is formed of Ti or TiN, for example. An opening is provided in the passivation film and the antireflection film to be located above the Al—Cu film. The sidewall protection film covers the sidewall of the opening provided in the passivation film and the antireflection film.

In the semiconductor device described in Japanese Unexamined Patent Application Publication No. Hei 11(1999)-312670, the sidewall protection film covers the sidewall of the opening provided in the passivation film and the antireflection film, thereby suppressing expansion in association with oxidation of Ti, TiN, or the like forming the antireflection film because of moisture. This is because, when Ti, TiN or the like forming the antireflection film expands, it is likely that a crack is introduced into the antireflection film to cause corrosion of wiring below the Al—Cu film.

### SUMMARY

In the semiconductor device described in Japanese Unexamined Patent Application Publication No. 2011-233746, photolithography and etching are used to cover the sidewall of the opening provided in the first passivation film and the TiN film with the second passivation film. Therefore, in the semiconductor device described in Japanese Unexamined Patent Application Publication No. 2011-233746, mask misalignment may occur when the sidewall of the opening provided in the first passivation film and the TiN film is covered with the second passivation film.

Thus, the semiconductor device described in Japanese Unexamined Patent Application Publication No. 2011-233746 must be designed in such a manner that the second passivation film remains to be relatively thick over the sidewall of the opening provided in the first passivation film and the TiN film in order to more surely cover that sidewall with the second passivation film, considering that mask misalignment. That is, it is difficult to reduce the dimensions of the bonding pad in the semiconductor device described in Japanese Unexamined Patent Application Publication No. 2011-233746.

In the semiconductor device described in Japanese Unexamined Patent Application Publication No. Hei 11(1999)-312670, the sidewall of the opening provided in the passivation film and the antireflection film is covered with the sidewall protection film by etching back a material forming the sidewall protection film. That is, in the semiconductor device described in Japanese Unexamined Patent Application Publication No. Hei 11(1999)-312670, mask misalignment does not occur when the sidewall of the opening provided in the passivation film and the antireflection film is covered with the sidewall protection film. Therefore, according to the semiconductor device described in Japanese Unexamined Patent Application Publication No. Hei 11(1999)-312670, it is relatively easy to reduce the dimensions of the bonding pad, as compared with the semiconductor device described in Japanese Unexamined Patent Application Publication No. 2011-233746.

However, when etching for forming the sidewall protection film is conducted, it is necessary to conduct over-etching to surely expose the Al—Cu film. This over-etching may make the surface of the Al—Cu film rough. The roughness of the surface of the Al—Cu film lowers the bonding property.

Other objects and novel features will be apparent from the description of this specification and the accompanying drawings.

A semiconductor device according to an embodiment includes a bonding pad containing aluminum, a titanium nitride film arranged over the bonding pad, a passivation film covering the bonding pad and the titanium nitride film, and a sidewall protection film including a first layer and a second layer. An opening is provided in the titanium nitride film and the passivation film. The opening includes a sidewall and exposes the bonding pad therethrough. The first layer of the sidewall protection film covers at least the titanium nitride film over the sidewall, and the second layer covers the first layer. A material forming the first layer and a material forming the second layer are different from each other in an etching rate in etching under the same condition.

According to a semiconductor device of an embodiment, a semiconductor device is provided which can prevent a surface of a bonding pad from being made rough and can reduce dimensions of the bonding pad.

### BRIEF DESCRIPTION OF THE DRAWINGS

FIG. 1 illustrates a schematic layout of a semiconductor device according to an embodiment.

FIG. 2 is a cross-sectional view, taken along a line II-II in FIG. 1.

FIG. 3 is a process chart illustrating a manufacturing method of a semiconductor device according to an embodiment.

FIG. 4 is a cross-sectional view in a bonding pad formation process S1 in the semiconductor device according to the embodiment.

FIG. 5 is a cross-sectional view in a passivation film formation process S2 in the semiconductor device according to the embodiment.

FIG. 6 is a cross-sectional view in an opening formation process S3 in the semiconductor device according to the embodiment.

FIG. 7 is a cross-sectional view in a first layer deposition process S41 in the semiconductor device according to the embodiment.

FIG. 8 is a cross-sectional view in a second layer deposition process S42 in the semiconductor device according to the embodiment.

FIG. 9 is a cross-sectional view in a first etching process S43 in the semiconductor device according to the embodiment.

### DETAILED DESCRIPTION

The details of an embodiment are described referring to the drawings. In the following drawings, the same or corresponding portions are labeled with the same reference sign, and redundant description is not repeated.

### Configuration of Semiconductor Device According to Embodiment

A configuration of a semiconductor device according to an embodiment is described below.

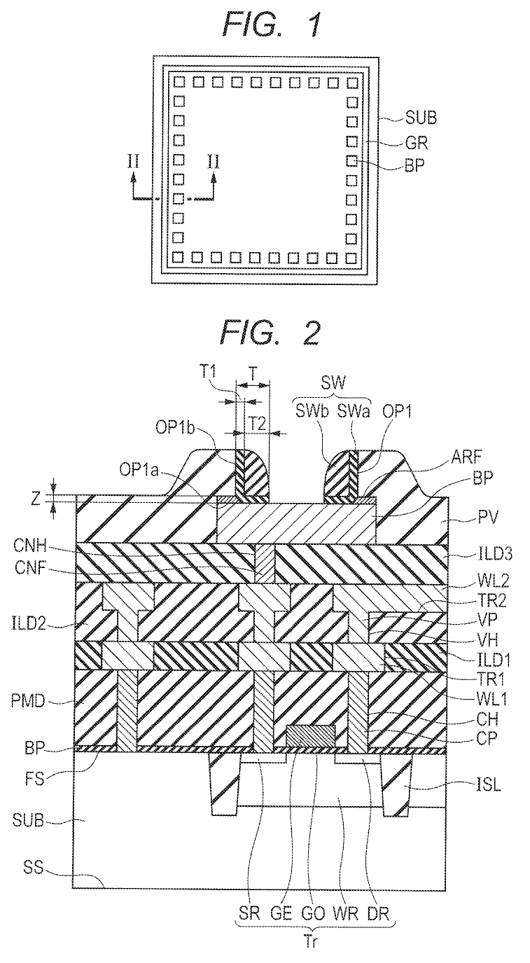

As illustrated in FIG. 1, the semiconductor device according to the embodiment includes a semiconductor substrate SUB, for example, formed of single-crystal silicon (Si). The semiconductor device according to the embodiment includes a guard ring GR. The guard ring GR is provided along the outer circumference of the semiconductor substrate SUB in a plan view. The guard ring GR suppresses progress of a crack, which is generated in dicing for separating a semiconductor wafer into a plurality of semiconductor substrates SUB, into the inside of each semiconductor substrate SUB.

The semiconductor device according to the embodiment includes a bonding pad BP. The bonding pad BP is arranged inside the guard ring GR in a plan view. The bonding pad BP is arranged along the guard ring GR. However, the arrangement of the bonding pad BP illustrated in FIG. 1 is merely an example, and is not limited thereto. The bonding pad BP contains Al. That is, the bonding pad BP is made of Al or Al alloy. The semiconductor device according to the embodiment is electrically coupled to the outside by wire bonding or the like conducted for the bonding pad BP.

As illustrated in FIG. 2, the semiconductor substrate SUB has a first surface FS and a second surface SS. The first surface FS and the second surface SS configure main surfaces of the semiconductor substrate SUB. The second surface SS is an opposite surface to the first surface FS.

The semiconductor substrate SUB includes a source region SR, a drain region DR, and a well region WR. The source region SR and the drain region DR are arranged in the first surface FS. The source region SR and the drain region DR are spaced from each other. The conductivity type of the source region SR and the drain region DR is a first conductivity type (for example, an n-type).

The well region WR is arranged to surround the source region SR and the drain region DR in the first surface FS. The well region WR includes a portion sandwiched between the source region SR and the drain region DR in the first surface FS (hereinafter, this portion is referred to as a channel region). The conductivity type of the well region WR is a second conductivity type (for example, an n-type) opposite to the first conductivity type.

The semiconductor device according to the embodiment includes a gate insulating film GO. The gate insulating film GO is arranged over the first surface FS. More specifically, the gate insulating film GO is arranged over the channel region. The gate insulating film GO is formed of silicon dioxide (SiO₂), for example.

The semiconductor device according to the embodiment includes a gate electrode GE. The gate electrode GE is arranged over the gate insulating film GO. The gate electrode GE is opposed to the channel region while being insulated therefrom by the gate insulating film GO. The gate electrode GE is formed of polycrystalline Si doped with impurity, for example.

The semiconductor device according to the embodiment includes a transistor Tr. The transistor Tr is configured by the source region SR, the drain region DR, the well region WR, the gate insulating film GO, and the gate electrode GE.

The semiconductor device according to the embodiment includes an element isolation layer ISL. The element isolation layer ISL is arranged in the first surface FS. The element isolation layer ISL surrounds the transistor Tr in a plan view to insulate and isolate the transistor Tr.

The semiconductor device according to the embodiment includes a pre-metal insulating film PMD. The pre-metal insulating film PMD is arranged to cover the transistor Tr over the first surface FS. Contact holes CH are provided in the pre-metal insulating film MD to be located above the source region SR, the drain region DR, and the gate electrode GE, respectively, and to penetrate through the pre-metal insulating film PMD in the thickness direction (although the contact hole CH located above the gate electrode GE is not illustrated in FIG. 2). The pre-metal insulating film PMD is formed of SiO₂, for example.

The semiconductor device according to the embodiment includes a contact plug CP. The contact plug CP is embedded in the contact hole CH. The contact plug CP is electrically coupled to the source region SR, the drain region DR, and the gate electrode GE. The contact plug CP is formed of tungsten (W), for example.

The semiconductor device according to the embodiment includes an interlayer dielectric film ILD1. The interlayer dielectric film ILD1 is arranged over the pre-metal insulating film PMD. A trench TR1 is provided in the interlayer dielectric film ILD1. The trench TR1 penetrates through the interlayer dielectric film ILD1 in the thickness direction. The interlayer dielectric film ILD1 is formed of SiO₂, for example.

The semiconductor device according to the embodiment includes a wiring layer WL1. The wiring layer WL1 is embedded in the trench TR1. The wiring layer WL1 is electrically coupled to the contact plug CP. The wiring layer WL1 is formed of Cu or CU alloy, for example.

The semiconductor device according to the embodiment includes an interlayer dielectric film ILD2. The interlayer dielectric film ILD2 is arranged over the interlayer dielectric film ILD1. A trench TR2 is provided in the interlayer dielectric film ILD2. The trench TR2 extends from the top surface of the interlayer dielectric film ILD2 towards the interlayer dielectric film ILD1. The trench TR2 does not penetrate through the interlayer dielectric film ILD2 in the thickness direction. A via hole VH is provided in the interlayer dielectric film ILD2. The via hole VH is arranged in a portion of the interlayer dielectric film ILD2 in which the trench TR2 is provided. The via hole VH penetrates through the interlayer dielectric film ILD2 in the thickness direction to expose the wiring layer WL1. The via hole VH is connected to the trench TR2.

The semiconductor device according to the embodiment includes a via plug VP and a wiring layer WL2. The via plug VP is embedded in the via hole VH. The wiring layer WL2 is embedded in the trench TR2. The wiring layer WL1 and the wiring layer WL2 are electrically coupled to each other by the via plug VP. The via plug VP and the wiring layer WL2 are formed integrally with each other. The via plug VP and the wiring layer WL2 are formed of Cu or CU alloy, for example.

The semiconductor device according to the embodiment includes an interlayer dielectric film ILD3. The interlayer dielectric film ILD3 is arranged over the interlayer dielectric film ILD2. A connection hole CNH is formed in the interlayer dielectric film ILD3. The connection hole CNH penetrates through the interlayer dielectric film ILD3 in the thickness direction. The interlayer dielectric film ILD3 is formed of SiO₂, for example.

The semiconductor device according to the embodiment includes a conductor film CNF. The conductor film CNF is embedded in the connection hole CNH. The conductor film CNF is electrically coupled to the wiring layer WL2. The conductor film CNF is formed of W, for example.

In the above description, a case where the number of wiring layers is two has been described. However, the semiconductor device according to the embodiment can include a wiring structure of three or more wiring layers by repeatedly arranging a structure that is configured by the interlayer dielectric film ILD2 with the trench TR2 and the via hole VH provided therein, the via plug VP, and the wiring layer WL2.

The bonding pad BP is arranged over the interlayer dielectric film ILD3. The bonding pad BP is electrically coupled to conductor film CNF.

The semiconductor device according to the embodiment includes a titanium nitride film ARF. The titanium nitride film ARF is arranged over the bonding pad BP. The titanium nitride film ARF serves as an antireflection film in photolithography conducted for a passivation film PV described later. The titanium nitride film ARF is also provided for preventing a hillock and electromigration in the surface of the bonding pad BP. The titanium nitride film ARF has a thickness Z.

The titanium nitride film ARF can be also arranged between the interlayer dielectric film ILD3 and the bonding pad BP, although not illustrated in FIG. 2.

The semiconductor device according to the embodiment includes the passivation film PV. The passivation film PV is arranged to cover the bonding pad BP and the titanium nitride film ARF. The passivation film PV is formed of silicon nitride (SiN), for example.

The semiconductor device according to the embodiment can include an adhesive insulating film, although not illustrated in FIG. 2. This adhesive insulating film is arranged between the passivation film PV, and the bonding pad BP and the titanium nitride film ARF. This adhesive insulating film is formed of SiO₂, for example.

An opening OP1 is provided in the passivation film PV and the titanium nitride film ARF. The opening OP1 penetrates through the passivation film PV and the titanium nitride film ARF in the thickness direction. That is, the opening OP1 exposes the bonding pad BP therethrough. In a case where the adhesive insulating film described above is arranged, the opening OP1 also penetrates through the adhesive insulating film in the thickness direction.

The sidewall of the opening OP1 includes a first portion OP1a and a second portion OP1b. The first portion OP1a is the sidewall of the opening OP1 in a portion formed by the titanium nitride film ARF, and the second portion OP1b is the sidewall of the opening OP1 in a portion formed by the passivation film PV.

The semiconductor device according to the embodiment includes a sidewall protection film SW. The sidewall protection film SW covers the sidewall of the opening OP1. The sidewall protection film SW has a thickness T. The thickness T is the maximum value of the thickness of the sidewall protection film SW in a direction parallel to the surface of the bonding pad BP. The thickness T is preferably 1.5 times or more the thickness Z. The bonding pad BP is exposed between the sidewall protection films SW covering the opposed sidewalls of the opening OP1.

The sidewall protection film SW includes a first layer SWa and a second layer SWb. The first layer SWa covers the sidewall of the opening OP1. More specifically, the first layer SWa covers the first portion OP1a and the second portion OP1b. The first layer SWa can cover a portion of the bonding pad BP that is exposed through the opening OP1. That is, the first layer SWa can be L-shaped. The first layer SWa has a thickness T1.

The second layer SWb is arranged to cover the first layer SWa. The second layer SWb has a thickness T2. The thickness T2 is the maximum value of the thickness of the second layer SWb in the direction parallel to the surface of the bonding pad BP. It is preferable that the thickness T2 is larger than the thickness T1 (the thickness T1 is smaller than the thickness T2). The thickness T is equal to the sum of the thickness T1 and the thickness T2.

A material forming the first layer SWa and a material forming the second layer SWb are selected to achieve different etching rates from each other in etching under the same condition. More specifically, the first layer SWa and the second layer SWb are selected in such a manner that an etching rate of the first layer SWa in first etching that removes the second layer SWb is smaller than an etching rate of the second layer SWb in the first etching, and an etching rate of the second layer SWb in second etching that removes the first layer SWa is smaller than an etching rate of the first layer SWa in the second etching.

For example, in a case where the second layer SWb is formed of SiO₂ (silicon oxide), SiON (silicon oxynitride) or SiN (silicon nitride) can be used for the first layer SWa.

### Manufacturing Method of Semiconductor Device According to Embodiment

A manufacturing method of a semiconductor device according to an embodiment is described below.

In the manufacturing method of the semiconductor device according to the embodiment, the source region SR, the drain region DR, and the well region WR, the gate insulating film GO, the gate electrode GE, the element isolation layer ISL, the pre-metal insulating film PMD, the contact plug CP, the interlayer dielectric films ILD1 to ILD3, the wiring layers WL1 and WL2, the via plug VP, and the conductor film CNF are formed by a conventional known method.

Formation of the above components is briefly described. The source region SR, the drain region DR, and the well region WR are formed by ion implantation, for example. The gate insulating film GO is formed by thermal oxidation of the first surface FS of the semiconductor substrate SUB, for example. The gate electrode GE is formed by depositing a material forming the gate electrode GE and patterning the deposited material by photolithography and etching.

In formation of the element isolation layer ISL, first, a groove is formed in the first surface FS by anisotropic etching, for example, RIE (Reactive Ion Etching). Second, a material forming the element isolation layer ISL is embedded in that groove by CVD (Chemical Vapor Deposition), for example, and the material forming the element isolation layer ISL protruding from that groove is removed by CMP (Chemical Mechanical Polishing), for example.

The pre-metal insulating film PMD is formed by depositing a material forming the pre-metal insulating film PMD by CVD or the like and flattening that deposited material by CMP.

The contact plug CP is formed by embedding a material forming the contact plug CP in the contact hole CH formed in the pre-metal insulating film PMD by anisotropic etching, such as RIE, by CVD, for example, and then removing the material forming the contact plug CP that protrudes from the contact hole CH by CMP, for example.

Each of the interlayer dielectric layers ILD1 to ILD3 is formed by depositing a material forming that interlayer dielectric layer ILD1, ILD2, or ILD3 by CVD, for example. The wiring layer WL1 is formed by a single-damascene method, for example. The wiring layer WL2 is formed by a dual-damascene method, for example.

The conductor film CNF is formed by embedding a material forming the conductor film CNF in the connection hole CNH formed in the interlayer dielectric layer ILD3 by anisotropic etching, such as RIE, by CVD, for example, and then removing the material forming the conductor film CNF that protrudes from the connection hole CNH by CMP, for example.

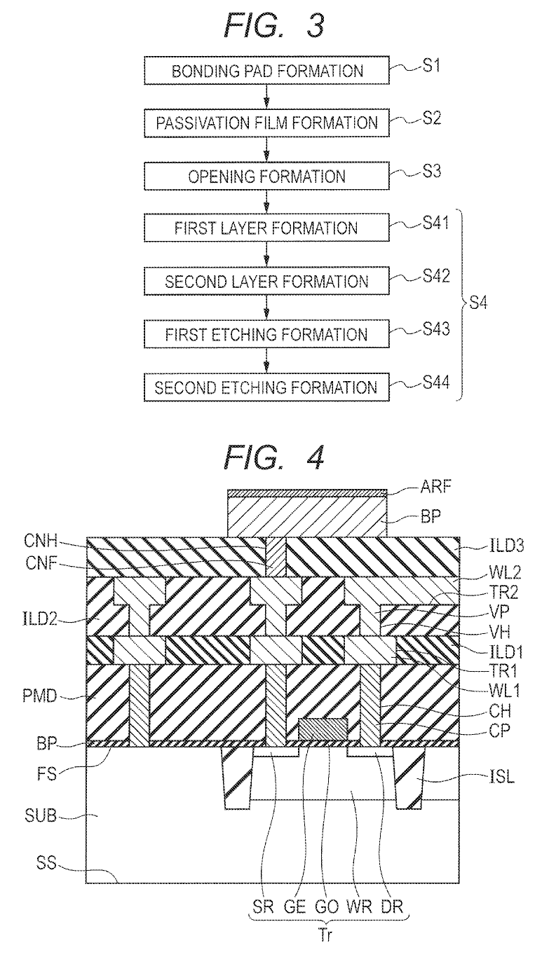

As illustrated in FIG. 3, the manufacturing method of the semiconductor device according to the embodiment includes a bonding pad formation process S1, a passivation film formation process S2, an opening formation process S3, and a sidewall protection film formation process S4 after the conductor film CNF is formed. The sidewall protection film formation process S4 includes a first layer deposition process S41, a second layer deposition process S42, a first etching process S43, and a second etching process S44.

As illustrated in FIG. 4, in the bonding pad formation process S1, the bonding pad BP and the titanium nitride film ARF are formed. In the bonding pad formation process S1, first, a material forming the bonding pad BP is deposited over the interlayer dielectric film ILD3 by sputtering, for example.

In the bonding pad formation process S1, second, titanium nitride is deposited over the deposited material forming the bonding pad BP by sputtering, for example. Titanium nitride is deposited to have the thickness Z.

In the bonding pad formation process S1, third, the material forming the bonding pad BP and titanium nitride that have been deposited are patterned by photolithography and etching. By the above steps, the bonding pad BP and the titanium nitride film ARF arranged over the bonding pad BP are formed.

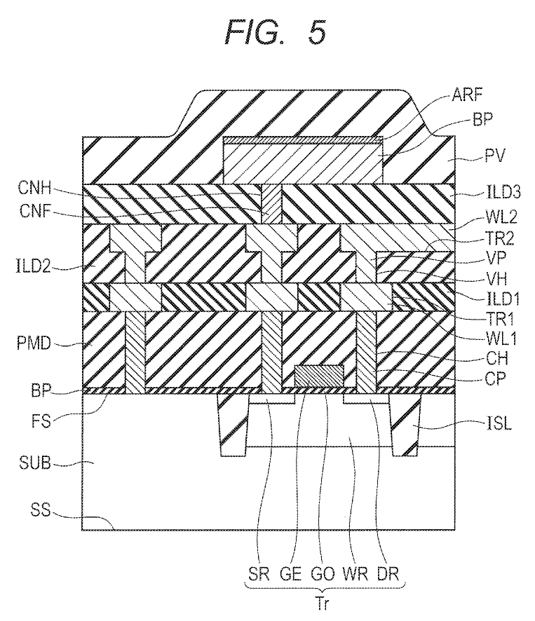

As illustrated in FIG. 5, the passivation film PV is formed in the passivation formation process S2. The passivation film PV is formed by depositing a material forming the passivation film PV to cover the bonding pad BP and the titanium nitride film ARF by CVD, for example.

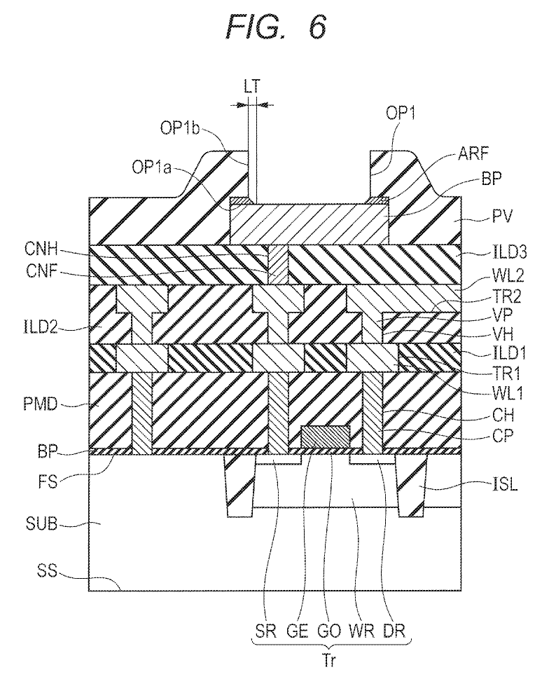

As illustrated in FIG. 6, the opening OP1 is formed in the opening formation process S3. The opening OP1 penetrates through the passivation film PV and the titanium nitride film ARF in the thickness direction. The opening OP1 is formed by photolithography and etching. Formation of the opening OP1 is achieved by anisotropic etching, such as RIE. By conducting the opening formation process S3, the bonding pad BP is exposed through the opening OP1.

Even when anisotropic etching is conducted, the first portion OP1a is inclined with respect to the top surface of the bonding pad BP at an obtuse angle (trailing occurs). According to the study by the inventors, the amount of trailing FT (the distance between an end of the first portion OP1a in the direction parallel to the surface of the bonding pad BP, which is a closer end to the second portion OP1b, and an end of the first portion OP1a closer to the bonding pad BP) is about 1.5 times the thickness Z.

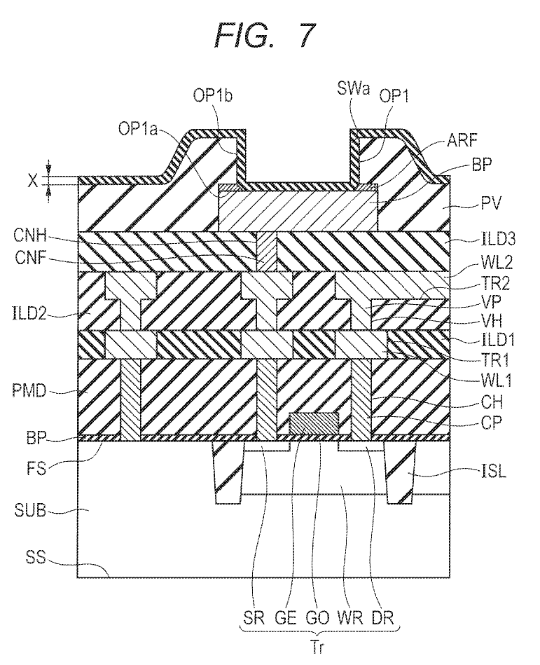

As illustrated in FIG. 7, the first layer SWa is deposited in the first layer deposition process S41. The first layer SWa is deposited by CVD, for example. In the first layer deposition process S41, the first layer SWa is deposited to have a thickness X. The deposited first layer SWa covers the top surface of the passivation film PV, the sidewall of the opening OP1, and the bonding pad BP exposed through the opening OP1.

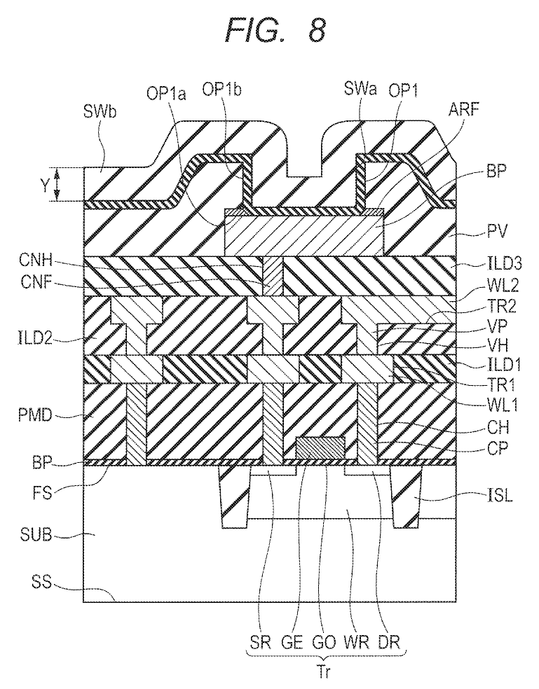

As illustrated in FIG. 8, the second layer SWb is deposited in the second layer deposition process S42. The second layer SWb is deposited by CVD, for example. In the second layer deposition process S42, the second layer SWb is deposited to have a thickness Y. The deposited second layer SWb covers the top surface of the first layer SWa, the sidewall of the opening OP1, and the first layer SWa covering the bonding pad BP exposed through the opening OP1.

The thickness X (unit: nm), the thickness Y (unit: nm), and the thickness Z (unit: nm) preferably satisfy the relationship of X+0.8Y−1.5Z>0. More preferably, the thickness, X, the thickness Y, and the thickness Z satisfy the relationship of 0.9X+0.72Y−1.5Z>0.

The thickness, X, the thickness Y, and the thickness Z can satisfy the relationship of X+0.8Y−1.5Z<400 nm. The thickness, X, the thickness Y, and the thickness Z can satisfy the relationship of 0.9X+0.72Y−1.5Z<400 nm.

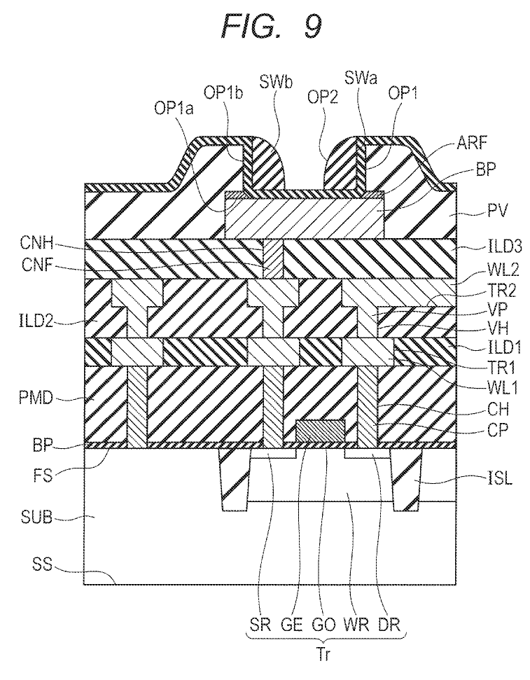

As illustrated in FIG. 9, the second layer SWb is etched (first etching) in the first etching process S43. The first etching is achieved by anisotropic etching, such as RIE. The first etching is conducted until the top surface of the first layer SWa is exposed. That is, in the first etching process S43, the second layer SWb is etched back. As a result of the first etching, the second layer SWb remains in the opening OP1 to cover the first layer SWa covering the sidewall of the opening OP1. Further, an opening OP2 is formed between the remaining second layers SWb. Through the opening OP2, the first layer SWa covering the bonding pad BP exposed through the opening OP1 is exposed.

Since the etching rate of the second layer SWb in the first etching is higher than the etching rate of the first layer SWa in the first etching as described above, the first layer SWa serves as an etch stopper for the first etching.

In the second etching process S44, the first layer SWa is etched (second etching). The second etching is achieved by anisotropic etching, such as RIE. The second etching is conducted until the bonding pad BP is exposed. By the above processes, the structure of the semiconductor device illustrated in FIG. 2 is formed.

The first etching is conducted by using the second layer SWb remaining to cover the first layer SWa covering the sidewall of the opening OP1 as mask in the first etching process S43. The reason why the second layer SWb serves as mask is that the etching rate of the first layer SWa in the second etching is higher than the etching rate of the second layer SWb in the second etching.

From the study of the inventors, the width of the second layer SWb remaining to cover the first layer SWa covering the sidewall of the opening OP1 in the first etching process S43 is reduced to about 0.8 times in the second etching process S44. That is, after the second etching process S44 is finished, the width of the second layer SWb covering the first layer SWa covering the sidewall of the opening OP1 (that is, the thickness T2 of the second layer SWb configuring a portion of the sidewall protection film SW) is about 0.8 times the thickness Y.

The thickness of the first layer SWa covering the sidewall of the opening OP1 is nearly unchanged even after the second etching process S44 is finished, because that first layer SWa is always covered by the second layer SWb in the first etching and the second etching. Therefore, the thickness T1 of the first layer SWa configuring a portion of the sidewall protection film SW is about X. From the above, the thickness T of the sidewall protection film SW (the sum of the thickness T1 and the thickness T2) is about X+0.8Y.

The study by the inventors has revealed that the thickness X and the thickness Y each include a variation of about ±10%. Therefore, the thickness T of the sidewall protection film SW is at least about 0.9X+0.72Y, even when such a variation is taken into consideration.

### Advantageous Effects of Semiconductor Device According to Embodiment and Manufacturing Method of Semiconductor Device According to Embodiment

Advantageous effects of the semiconductor device according to the embodiment and the manufacturing method of the semiconductor device according to the embodiment are described below.

In the semiconductor device according to the embodiment, the sidewall protection film SW can be formed in a self-aligned manner without using photolithography. The thickness T of the sidewall protection film SW can be controlled by the thicknesses of the first layer SWa and the second layer SWb (the thickness X and the thickness Y). Since a variation of the thickness of each of the first layer SWa and the second layer SWb is relatively small (about ±10%), it is possible to precisely control the thickness T of the sidewall protection film SW in the semiconductor device according to the embodiment. Consequently, it is possible to suppress exposure of the titanium nitride film ARF without making the thickness T of the sidewall protection film SW excessively large. Therefore, according to the semiconductor device of the embodiment, it is possible to reduce the dimensions of the bonding pad BP.

Further, in the semiconductor device according to the embodiment, the sidewall protection film SW is configured by two layers, i.e., the first layer SWa and the second layer SWb. Therefore, the first layer SWa becomes thin, as compared with a case where the sidewall protection film SW is configured by the first layer SWa only. As a result, the amount of over-etching when the first layer SWa is etched can be reduced, roughness of the surface of the bonding pad BP can be suppressed.

In the semiconductor device according to the embodiment, when the thickness T1 is smaller than the thickness T2, it is possible to further reduce the amount of over-etching when the first layer SWa is etched. Therefore, in this case, it is possible to further suppress roughness of the surface of the bonding pad BP.

The thickness T of the sidewall protection film SW is approximately X+0.8Y, as described above. Meanwhile, the amount of trailing FT of the titanium nitride film ARF is approximately 1.5Z, as described above. Therefore, when X+0.8Y−1.5Z>0 (that is, the thickness T−1.5Z>0), it is possible to cover the titanium nitride film ARF with the sidewall protection film SW.

The thickness X and the thickness Y may each include a variation of about ±10%. Considering such a variation, the thickness T of the sidewall protection film SW is at least 0.9X+0.72Y. Therefore, when the relationship of 0.9X+0.72Y−1.5Z>0 is satisfied, it is possible to cover the titanium nitride film ARF with the sidewall protection film SW more surely.

When the sidewall protection film SW is formed by conducting photolithography, it is necessary to consider a margin of overlapping mask for two times. In particular, since photoresist for a passivation film is a rough process, a required margin of overlapping mask is about 420 nm according to the study by the inventors. Therefore, in this case, if a value obtained by subtracting the amount of trailing FT from the thickness T of the sidewall protection film SW (this value may be referred to as an overlapping amount below) is not 420 nm or more, it is likely that the titanium nitride film ARF is not covered by the sidewall protection film SW because of mask misalignment.

When the overlapping amount becomes large, the width of the bonding pad BP exposed between the sidewall protection films SW becomes small. Therefore, it becomes difficult to reduce the dimensions of the bonding pad BP.

According to the manufacturing method of the semiconductor device of the embodiment, it is possible to control the thickness T of the sidewall protection film SW by the thickness X and the thickness Y that can be controlled relatively precisely. Therefore, the overlapping amount can be made small.

More specifically, according to the manufacturing method of the semiconductor device of the embodiment, it is possible to satisfy the relationship of X+0.8Y−1.5Z (=the overlapping amount)<400 nm (or 0.9X+0.72Y−1.5Z<400 nm). The above relationship also shows that according to manufacturing method of the semiconductor device of the embodiment, it is possible to reduce the dimensions of the bonding pad BP.

In the above, the invention made by the inventors of the present application has been specifically described by way of the embodiment. However, it is naturally understood that the present invention is not limited to the aforementioned embodiment, and can be changed in various ways within the scope not departing from the gist thereof.

What is claimed is:

1. A semiconductor device comprising:
a bonding pad containing aluminum;
a passivation film covering the bonding pad; and
a sidewall protection film including a first layer and a second layer,
wherein an opening is provided in the passivation film and includes a sidewall and exposes the bonding pad therethrough,
wherein the first layer of the sidewall protection film covers the sidewall, and the second layer covers the first layer, and
wherein a material forming the first layer and a material forming the second layer are different from each other.

2. The semiconductor device according to claim 1, further comprising a titanium nitride film arranged over the bonding pad,
wherein the opening is further provided in the titanium nitride film, and
wherein the first layer further covers the titanium nitride film.

3. The semiconductor device according to claim 2, wherein a thickness of the first layer in a direction parallel to a surface of the bonding pad is smaller than a thickness of the second layer in the direction parallel to the surface of the bonding pad.

4. The semiconductor device according to claim 3,
wherein the first layer is formed of silicon nitride, and
wherein the second layer is formed of silicon oxide.

5. The semiconductor device according to claim 4, wherein a thickness of the sidewall protection film in a direction parallel to the surface of the bonding pad is 1.5 times or more a thickness of the titanium nitride film.

6. A manufacturing method of a semiconductor device, comprising:
forming a bonding pad containing aluminum;
forming a passivation film covering the bonding pad and the titanium nitride film;
forming a first opening in the passivation film to expose the bonding pad therethrough;
forming a first layer covering the passivation film, a sidewall of the first opening, and the bonding pad exposed through the first opening;
forming a second layer covering the first layer;
forming a second opening in the second layer to expose the first layer therethrough by conducting first etching for the second layer; and
conducting second etching for the first layer by using the second layer in which the second opening is provided as mask to expose the bonding pad,
wherein an etching rate of the second layer in the first etching is higher than an etching rate of the first layer in the first etching, and
wherein an etching rate of the first layer in the second etching is higher than an etching rate of the second layer in the second etching.

7. The manufacturing method according to claim 6, further comprising forming a titanium nitride film over the bonding pad,
wherein the first opening is further formed in the titanium nitride in the forming the first opening.

8. The manufacturing method according to claim 7, wherein a thickness of the first layer is smaller than a thickness of the second layer.

9. The manufacturing method according to claim 8,
wherein the first layer is formed of silicon nitride, and
wherein the second layer is formed of silicon oxide.

10. The manufacturing method according to claim 9, wherein a relationship of X+0.8Y−1.5Z>0 is satisfied where the thickness of the first layer is X (unit: nm), the thickness of the second layer is Y (unit: nm), and a thickness of the titanium nitride film is Z (unit: nm).

11. The manufacturing method according to claim 10, wherein a relationship of X+0.8Y−1.5Z<400 is satisfied.

12. The manufacturing method according to claim 9, wherein a relationship of 0.9X+0.72Y−1.5Z>0 is satisfied where the thickness of the first layer is X (unit: nm), the thickness of the second layer is Y (unit: nm), and a thickness of the titanium nitride film is Z (unit: nm).

13. The manufacturing method according to claim 12, wherein
a relationship of 0.9X+0.72Y−1.5Z<400 is satisfied.
